(19) United States
(12) Patent Application Publication
(10) Pub. No.: US 2018/0182682 A1
(43) Pub. Date: Jun. 28, 2018

(54) SEMICONDUCTOR DEVICE PACKAGE WITH STRESS RELIEF LAYER

(71) Applicant: POWERTECH TECHNOLOGY INC., HSINCHU COUNTY (TW)

(72) Inventor: Wen-Jeng Fan, HSINCHU COUNTY (TW)

(21) Appl. No.: 15/390,533

(22) Filed: Dec. 25, 2016

(51) Int. Cl. H01L 23/31; H01L 23/00; H01L 21/56; H01L 21/02

(52) U.S. Cl. CPC H01L 23/3114; H01L 2924/20641; H01L 24/14; H01L 21/568; H01L 21/565; H01L 21/02118; H01L 24/11; H01L 2224/13024; H01L 2224/13023; H01L 2224/0237; H01L 2224/0239; H01L 2924/01029; H01L 2924/01013; H01L 2224/02311; H01L 2924/351; H01L 2924/2064; H01L 23/562

(57) ABSTRACT

A semiconductor device package includes an encapsulation layer, a die, a stress relief layer, and a redistribution layer. The encapsulation layer has an opening, and the die is disposed in the opening of the encapsulation layer. The stress relief layer is disposed between the encapsulation layer and the die. The redistribution layer is formed on the die, the stress relief layer and the encapsulation layer.

### BACKGROUND OF THE INVENTION

### 1. Field of the Invention

This invention is related to a semiconductor device package, especially related to a semiconductor device package having a stress relief layer.

### 2. Description of the Prior Art

As the demand for reducing chip area of an electronic device increases, packaging semiconductor devices faces challenges to further size reduction. Due to the advantage of having a smaller package size, the Fan In or Fan Out chip scale packaging is one of the approaches to package semiconductor devices.

To reduce the area required by the pin assignment in CSP, the redistribution layer structure is used to reroute the input/output ports for increasing pitches of chip pads. A larger pitch between chip pads will ease the effort to mount terminal solder bumps or balls used for connecting to a substrate or printed circuit board (PCB).

As the number of input/output ports increases, some of the solder balls are disposed outside the chip area, creating a fan out structure. In this kind of fan out package, the redistribution layer is formed on two different materials, the silicon die and the encapsulation layer (e.g. epoxy molding compound) surrounding the silicon die. Since the coefficients of thermal expansion of the silicon die and the encapsulation layers are different (silicon 2˜4 ppm/C, encapsulation 10˜50 ppm/C), the structure of the redistribution layer can be damaged by serious thermal stress caused by severe temperature changes.

### SUMMARY OF THE INVENTION

One embodiment of the present invention discloses a semiconductor device package. The semiconductor device package includes an encapsulation layer, a die, a stress relief layer, and a redistribution layer.

The encapsulation layer has an opening, and the die is disposed in the opening of the encapsulation layer. The stress relief layer is disposed between the encapsulation layer and the die. The redistribution layer is formed on the die, the stress relief layer and the encapsulation layer. The stress relief layer can buffer stresses between the die and the encapsulation layer for preventing the redistribution layer from being damaged.

Another embodiment of the present invention discloses a method for forming a semiconductor device package. The method includes disposing a die on a carrier, forming a stress relief layer on the die, molding the die on the carrier to form an encapsulation layer surrounding the die, and forming a redistribution layer on the die, the stress relief layer and the encapsulation layer.

The stress relief layer can buffer stresses between the die and the encapsulation layer for preventing the redistribution layer from being damaged.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a cross-section of a semiconductor device according to one embodiment of the present invention.

FIG. 2 shows a top view of a semiconductor device according to another embodiment of the present invention.

FIG. 3 shows a flowchart of a method for forming the semiconductor device in FIG. 1 according to one embodiment of the present invention.

FIGS. 4 to 11 show the structures corresponding to steps of the method in FIG. 3 respectively.

FIG. 12 shows a flowchart of a method for forming the semiconductor device in FIG. 1 according to another embodiment of the present invention.

FIGS. 13 to 19 show the structures corresponding to steps of the method in FIG. 12 respectively.

### DETAILED DESCRIPTION

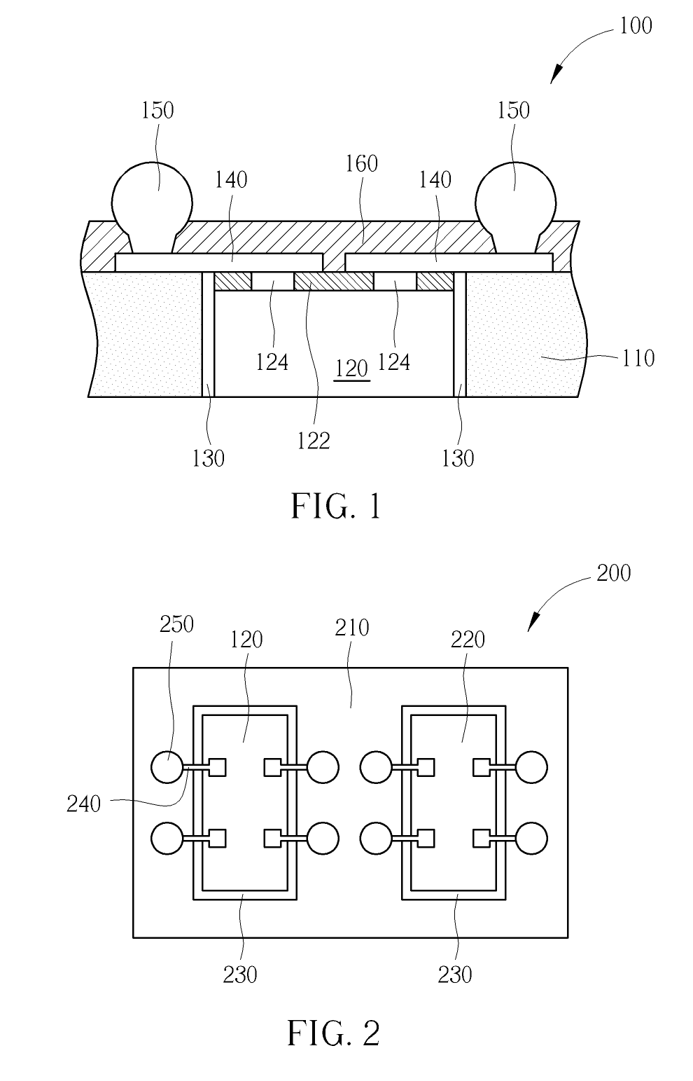

FIG. 1 shows a cross-section of a semiconductor device 100 according to one embodiment of the present invention. The semiconductor device 100 includes an encapsulation layer 110, a die 120, a stress relief layer 130, and a redistribution layer 140.

The encapsulation layer 110 may be formed by using a material such as an epoxy molding compound or resin. In FIG. 1, the encapsulation layer 110 has an opening where the die 120 is disposed in. The die 120 may be a chip sliced from a wafer and may be designed to perform operations through its input/output ports 124. The input/output pins 124 are disposed on an active surface of the die 120. In some embodiments, the die 120 may also include a dielectric layer 122 on its active surface with openings on the input/output ports 124 of the die 120. The dielectric layer 122 may be used to prevent the die 120 from being exposed, damaged or shorted unintentionally.

The redistribution layer 140 is formed on the die 120 and the encapsulation layer 110 for electrically connecting to the input/output ports 124 of the die 120. The redistribution layer 140 may be a layer of conductive material plated on the die 120 and the encapsulation layer 110. The conductive material may be copper, aluminum, metal alloys, or other types of conductive material.

In FIG. 1, the semiconductor device 100 further includes soldering bumps 150. The soldering bumps 150 are disposed on the redistribution layer 140 to electrically connect to corresponding input/output ports 124 of the die 120. Consequently, the input/output ports 124 of the die 120 can be rerouted to further use the area outside the periphery of the die 120.

In addition, the stress relief layer 130 may be disposed between the encapsulation layer 110 and the die 120. The stress relief layer 130 may be a thin film of low modulus material such as polymer, epoxy, polymeric material, resin, photo-sensitive resist, or a mixture of any two or more materials aforementioned. The thickness of the stress relief layer 130 may range from 15 to 100 micrometers. However, the thickness may not be limited to the aforementioned range. The thickness of the stress relief layer 130 may vary according to the available technology at a time. In some embodiments, the stress relief layer has a modulus lower than 200 MPa. The elastic and resilient characteristics of the low modulus material make the stress relief layer 130 a good buffering layer for absorbing stresses. The modulus coefficient of the stress relief layer 130 may be less than a modulus coefficient of the die 120 and the encapsulation layer 110. Therefore, although the coefficient of thermal expansion (CTE) of the die 120 and the coefficient of thermal expansion of the encapsulation layer 110 are different, the stress relief layer 130 may relief the stress between the die 120 and the encapsulation layer 110 caused by severe temperature changes, thereby preventing the redistribution layer 140 from being damaged.

That is, in FIG. 1, since the redistribution layer 140 is formed over the die 120, the stress relief layer 130 and the encapsulation layer 110, the stress relief layer 130 may absorb the stresses between the die 120 and the encapsulation layer 110 preventing the redistribution layer 140 from being distorted. Therefore, the semiconductor device 100 is able to endure severe temperature variation without deforming the redistribution layer 140.

Furthermore, in some embodiments, the coefficient of thermal expansion of the stress relief layer 130 may be between the coefficient of thermal expansion of the die 120 and the coefficient of thermal expansion of the encapsulation layer 110, with the coefficient of thermal expansion of the die 120 being the smallest.

In addition, before the soldering bumps 150 are planted, the semiconductor device 100 may further include a dielectric layer 160 disposed on the redistribution layer 140 where no soldering bumps 150 are disposed, thereby protecting the redistribution layer 140.

FIG. 2 shows a top view of a semiconductor device 200 according to another embodiment of the present invention. The semiconductor device 200 includes an encapsulation layer 210, two dies 120 and 220, a stress relief layer 230, a redistribution layer 240, and soldering bumps 250. The structure of the semiconductor device 200 is similar to the structure of the semiconductor device 100. That is, a cross-section view of the die 120 or the die 220 may have the same cross-section view as shown in FIG. 1. Also, in some embodiments, the semiconductor device may include even more dies according to the requirements.

Since the stress relief layer 230 with low modulus is formed between the dies 120, 220 and the encapsulation layer 210, the stress relief layer 230 may buffer the stresses caused by the different coefficients of thermal expansion of the dies 120, 220 and the encapsulation layer 210 under temperature variations, thereby preventing the redistribution layer 240 from being damaged.

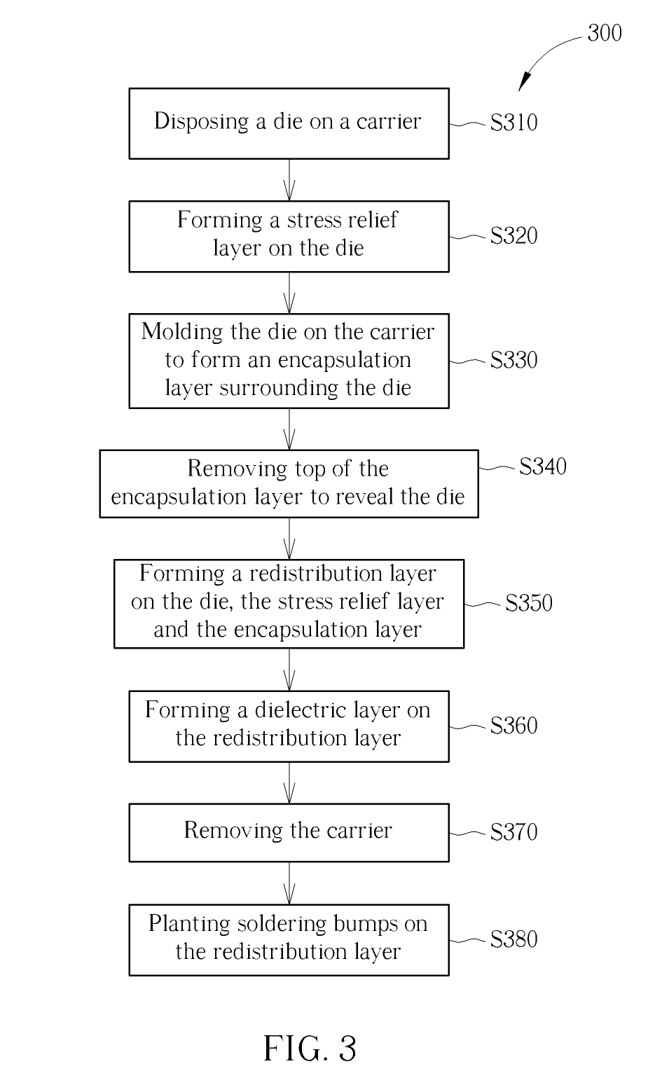

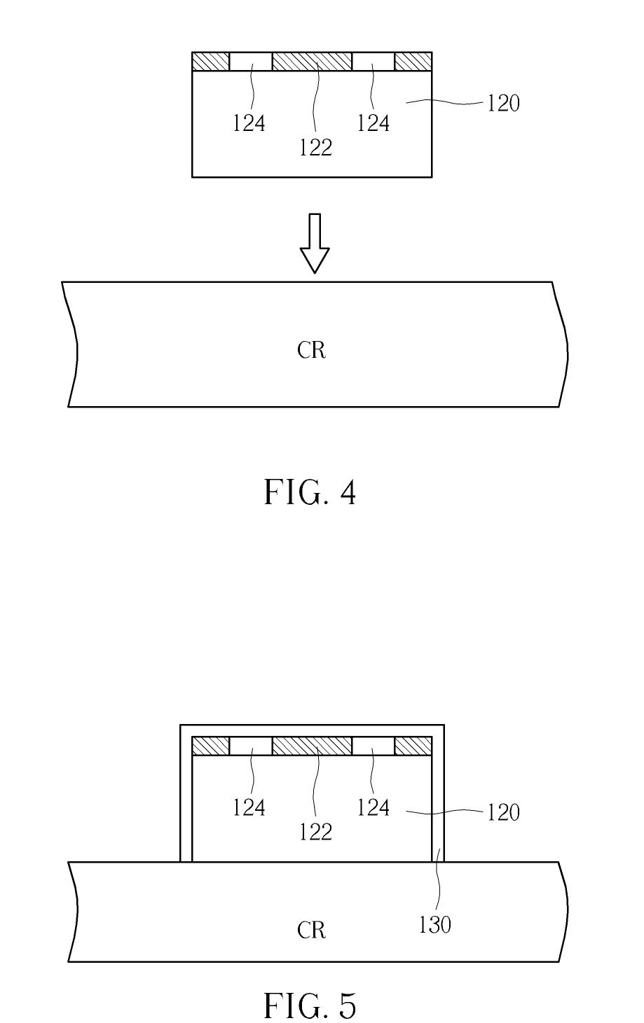

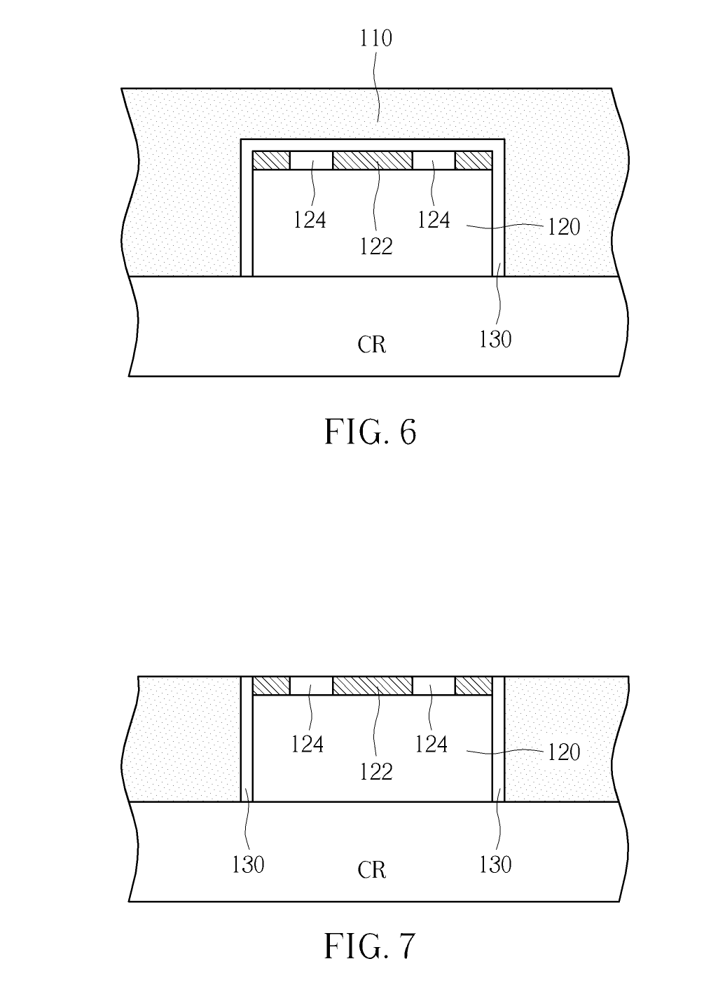

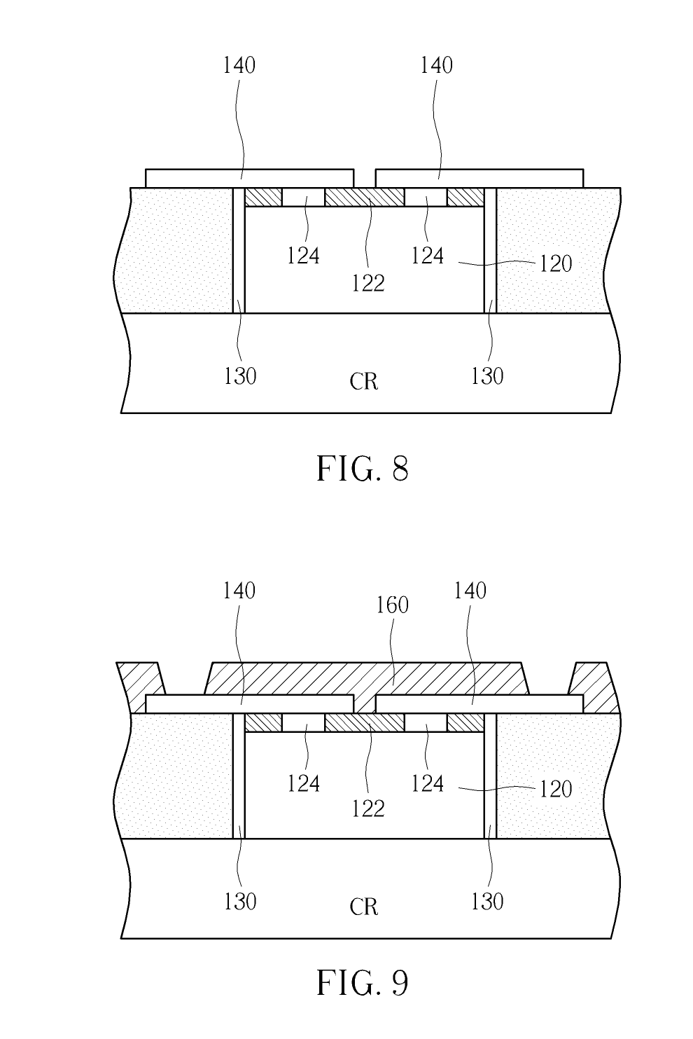

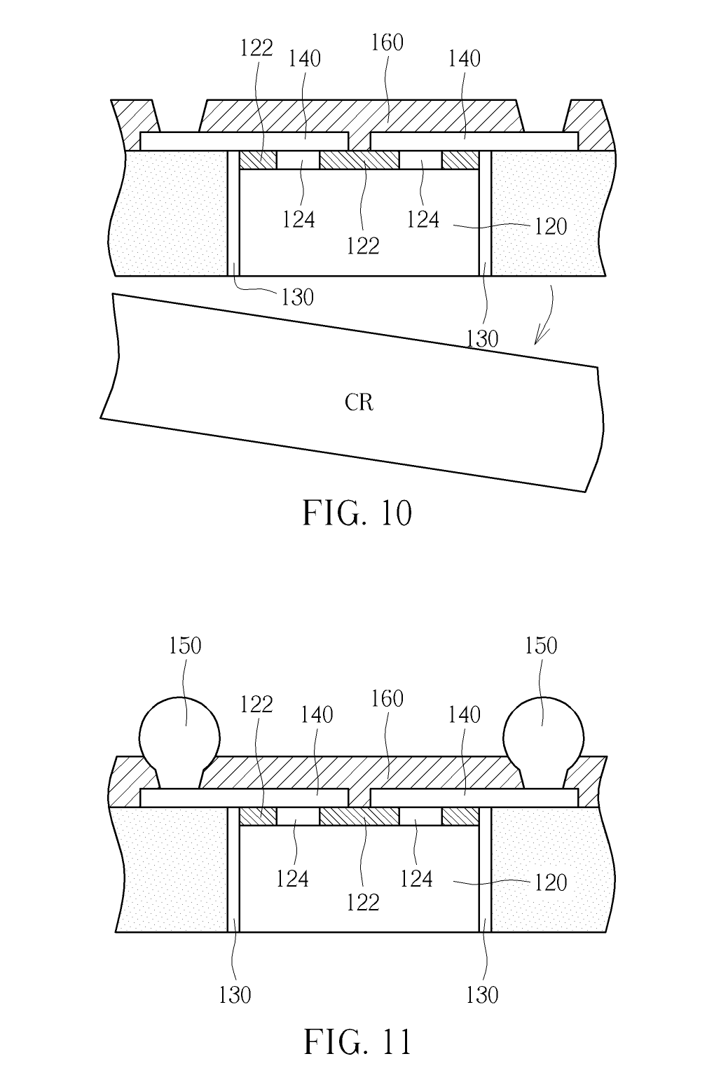

FIG. 3 shows a flowchart of a method 300 for forming the semiconductor device package 100. The method 300 includes steps S310 to S380. FIGS. 4 to 11 show the structures corresponding to steps S310 to S380 respectively.

S310: disposing a die 120 on a carrier CR;

S320: forming a stress relief layer 130 on the die 120;

S330: molding the die 120 on the carrier CR to form an encapsulation layer 110 surrounding the die 120;

S340: removing top of the encapsulation layer 110 to reveal the die 120;

S350: forming a redistribution layer 140 on the die 120, the stress relief layer 130 and the encapsulation layer 110;

S360: forming a dielectric layer 160 on the redistribution layer 140;

S370: removing the carrier CR;

S380: planting soldering bumps 150 on the redistribution layer 140.

In step S310, the die 120 may be disposed on the carrier CR by a fine alignment machine. In step S320, the stress relief layer 130 may be formed by spraying a thin film of low modulus material on the die 120. The low modulus material may be polymer, epoxy, polymeric material, resin, photo-sensitive resist, or a mixture of any two or more materials aforementioned.

In step S330, the encapsulation layer 110 is formed by molding the die 120 for protecting the die 120. In the present embodiment, the die 120 is disposed on the carrier CR with its face up; therefore, in step S340, the top of the encapsulation layer 110 is ground to reveal the die 120. In addition, during step S340, part of the low modulus material on the die 120 would also be removed while part of the low module material attached on sides of the die 120 is preserved. In some embodiments, step S340 can be performed by grinding and/or etching the encapsulation layer 110.

In step S350, the redistribution layer 140 is formed above the die 120, the stress relief layer 130 and the encapsulation layer 110 for rerouting the input/output ports 124 of the die 120. The redistribution layer 140 can be formed by plating a layer of conductive material on the die 120, the stress relief layer 130 and the encapsulation layer 110, and the conductive material can be copper, aluminum or other types of conductive material.

In step S360, the dielectric layer 160 may be formed on the redistribution layer 140 with openings through a mask for the planting of soldering bumps 150 later on. In step S370, the carrier CR is removed, and in step S380, the soldering bumps 150 are planted on the redistribution layer 140.

Although the method 300 is processed with the die 120 faced up when disposing the die 120 on the carrier CR, in some embodiments, the die 120 can be disposed on the carrier CR with its face down.

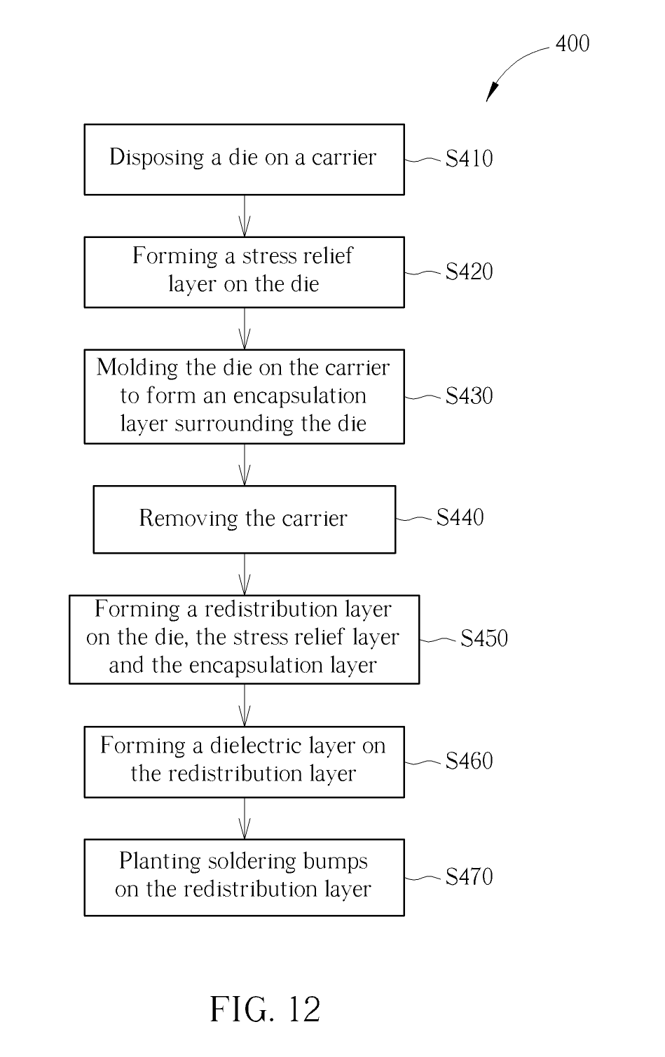

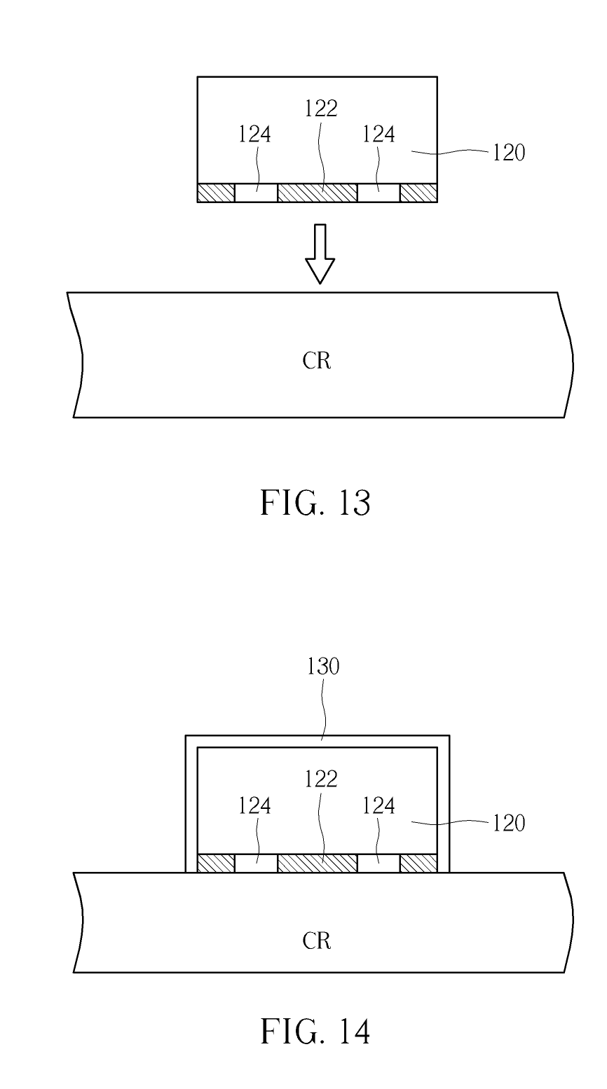

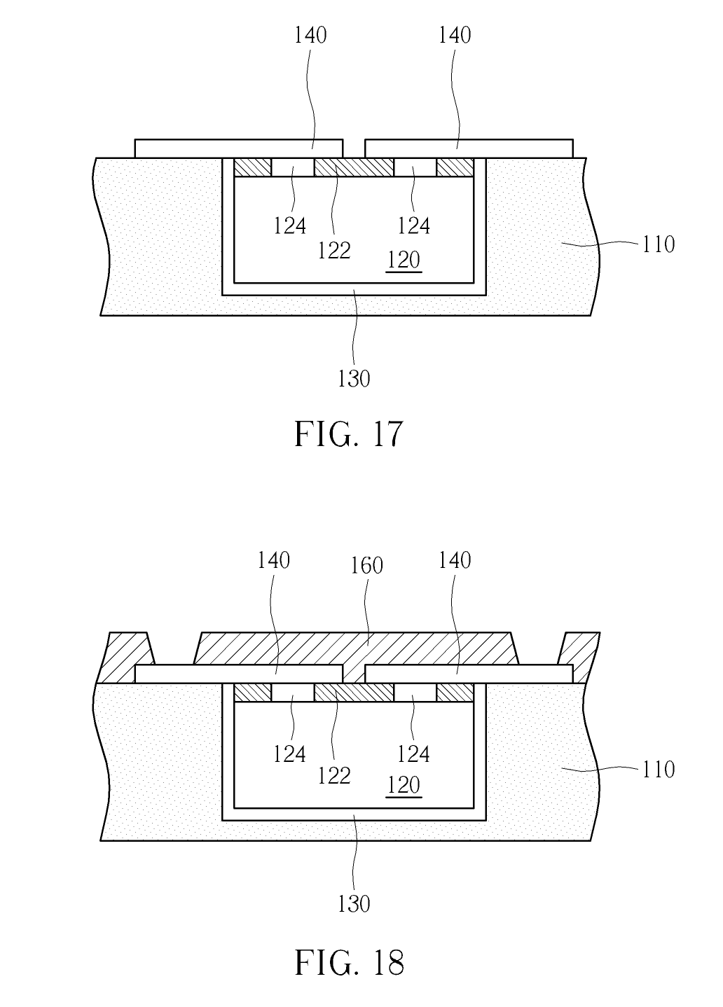

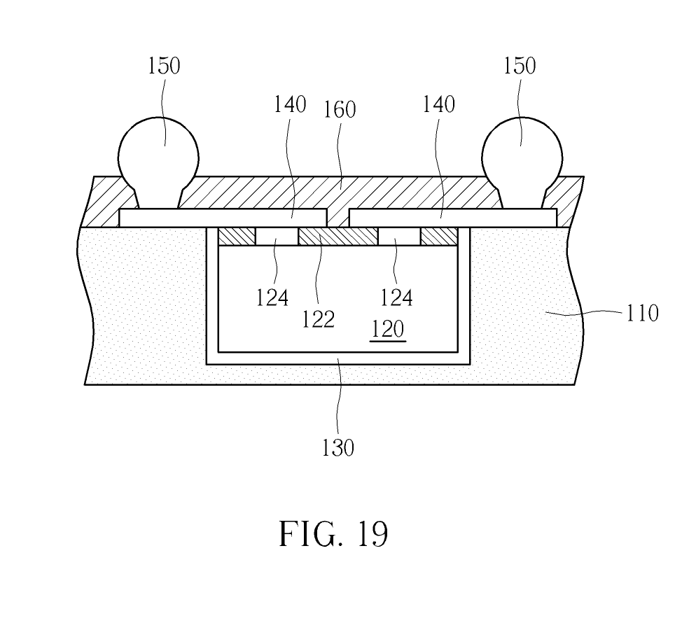

FIG. 12 shows a flowchart of a method 400 for forming the semiconductor device package 100. The method 400 includes steps S410 to S480. FIGS. 13 to 19 show the structures corresponding to steps S410 to S470 respectively.

S410: disposing a die 120 on a carrier CR;

S420: forming a stress relief layer 130 on the die 120;

S430: molding the die 120 on the carrier CR to form an encapsulation layer 110 surrounding the die 120;

S440: removing the carrier CR;

S450: forming a redistribution layer 140 on the die 120, the stress relief layer 130 and the encapsulation layer 110;

S460: forming a dielectric layer 160 on the redistribution layer 140;

S470: planting soldering bumps 150 on the redistribution layer 140.

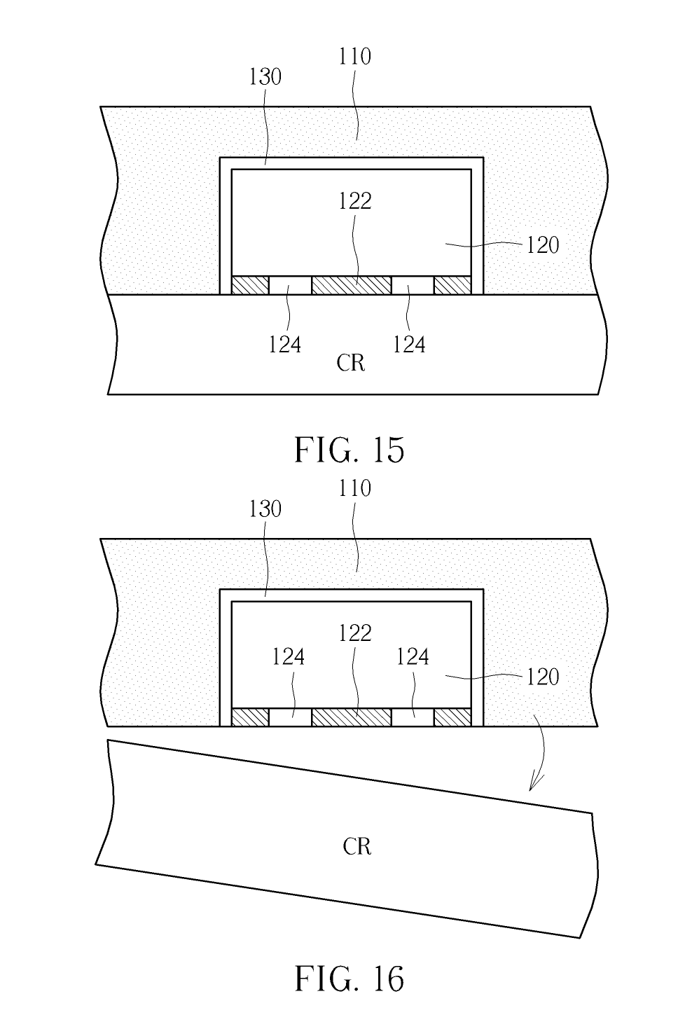

In step S410, the die 120 is disposed on the carrier CR with its face down; therefore, after the die 120 is molded in step S430, the carrier CR will be removed in step S440 to reveal the input/output ports 124 of the die 120. Consequently, the redistribution layer 140 can be formed on the die 120, the stress relief layer 130 and the encapsulation layer 110 in step S450. Also, in some embodiments, after the stress relief layer 130 is formed in step S420 and before the encapsulation layer 110 is formed in step S430, part of the stress relief layer 130 formed on the die 120 can be removed while part of the stress relief layer 130 attached to sides of the die 120 is preserved. However, this step of removing part of the stress relief layer 130 can be skipped in the some embodiments, such as shown in FIGS. 14 and 15.

In addition, to further thinner the semiconductor device 100, the method 300 may include a step of grinding the encapsulation layer 110 to reveal the back surface of the die 120 in some embodiments.

According to methods 300 and 400, since the stress relief layer 130 with low modulus is formed between the encapsulation layer 110 and the die 120, the stress caused by severe temperature variation can be absorbed by the stress relief layer 130. Therefore, the structure of the redistribution layer 140 can be protected.

In summary, the semiconductor device package and the method for forming the semiconductor device package provided by the embodiments of the present invention can adopt the stress relief layer between the die and the encapsulation layer to prevent the redistribution layer above the boundary of the encapsulation layer and the die from being distorted by the stresses caused by temperature change. Therefore, the semiconductor devices are able to endure the stress under extreme environment of varying temperature.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device package comprising:
an encapsulation layer having an opening;
a die disposed in the opening of the encapsulation layer;
a stress relief layer disposed between the encapsulation layer and the die; and
a redistribution layer formed on the die, the stress relief layer and the encapsulation layer;
wherein the stress relief layer is configured to buffer stresses between the die and the encapsulation layer for preventing the redistribution layer from being damaged.

2. The semiconductor device package of claim 1, wherein a thickness of the stress relief layer is 15 to 100 micrometers.

3. The semiconductor device package of claim 1, wherein the redistribution layer is of copper or aluminum.

4. The semiconductor device package of claim 1, wherein the redistribution layer is formed by plating.

5. The semiconductor device package of claim 1, wherein a coefficient of thermal expansion of the stress relief layer is between a coefficient of thermal expansion of the die and a coefficient of thermal expansion of the encapsulation layer.

6. The semiconductor device package of claim 5, wherein the coefficient of thermal expansion of the die is smaller than the coefficient of thermal expansion of the encapsulation layer.

7. The semiconductor device package of claim 1, further comprising soldering bumps disposed on the redistribution layer.

8. The semiconductor device package of claim 1, further comprising a dielectric layer formed on the redistribution layer.

9. The semiconductor device package of claim 1, wherein the stress relief layer is a thin film of low modulus material.

10. The semiconductor device package of claim 9, wherein the low modulus material comprises polymer, epoxy, polymeric material, resin, and/or photo-sensitive resist.

11. A method for forming a semiconductor device package comprising:
disposing a die on a carrier;
forming a stress relief layer on the die;
molding the die on the carrier to form an encapsulation layer surrounding the die; and
forming a redistribution layer on the die, the stress relief layer, and the encapsulation layer;
wherein the stress relief layer is configured to buffer stresses between the die and the encapsulation layer for preventing the redistribution layer from being damaged.

12. The method of claim 11, wherein forming the stress relief layer on the die is spraying a thin film of low modulus material on the die.

13. The method of claim 12, wherein the low modulus material comprises polymer, epoxy, polymeric material, resin, and/or photo-sensitive resist.

14. The method of claim 12, further comprising removing part of the low modulus material on the die while preserving part of the low module material attached on sides of the die.

15. The method of claim 11, wherein forming the redistribution layer on the die and the encapsulation layer is plating a layer of conductive material on the die and the encapsulation layer.

16. The method of claim 15, wherein the conductive material is of copper or aluminum.

17. The method of claim 11, wherein a coefficient of thermal expansion of the stress relief layer is between a coefficient of thermal expansion of the die and a coefficient of thermal expansion of the encapsulation layer.

18. The method of claim 17, wherein the coefficient of thermal expansion of the die is smaller than the coefficient of thermal expansion of the encapsulation layer.

19. The method of claim 11, further comprising planting soldering bumps on the redistribution layer.

20. The method of claim 11, further comprising forming a dielectric layer on the redistribution layer.
